(19) United States
(12) Patent Application Publication
(10) Pub. No.: US 2008/0090375 A1
(43) Pub. Date: Apr. 17, 2008

(54) METHOD FOR MANUFACTURING A SEMICONDUCTOR DEVICE INCLUDING A STACKED CAPACITOR

(75) Inventor: Hiroyuki KITAMURA, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/873,428

(22) Filed: Oct. 17, 2007

(30) Foreign Application Priority Data
Oct. 17, 2006 (JP) 2006-282943

(51) Int. Cl. H01L 21/283

(52) U.S. Cl. 438/396; 257/E21.159

(57) ABSTRACT

A process for forming a capacitor in a semiconductor device includes the step of forming a two-layer capacitor insulation film including a silicon oxynitride film and a tantalum oxide film. The step for forming the silicon oxynitride film is performed at a first substrate temperature, and the step of forming the tantalum oxide film uses a heat treatment performed at a second substrate temperature. The second substrate temperature is lower than the maximum of the first substrate temperature, to provide a higher capacitance per unit area and a lower leakage current in the capacitor.

This application is based upon and claims the benefit of priority from Japanese patent application No. 2006-282943, the disclosure of which is incorporated herein in its entirety by reference.

### BACKGROUND OF THE INVENTION

(a) Field of the Invention

The present invention relates to a method for manufacturing a semiconductor device and, more particularly, to a method for forming a stacked capacitor in a semiconductor device.

(b) Description of the Related Art

DRAM (dynamic random access memory) devices include an array of memory cells each for storing therein information. Each memory cell includes a MOSFET (metal-oxide-semiconductor field-effect-transistor) formed on a surface region of a silicon substrate and a storage capacitor or stacked capacitor overlying the MOSFET and connected thereto, and stores electric charge in the storage capacitor via the MOSFET. In recent years, the area occupied by each memory cell is drastically reduced along with development of the finer pattern in the DRAM devices. Therefore, it is desired to reduce the occupied area of the storage capacitor while maintaining a desired capacitance.

For securing the desired capacitance with a smaller occupied area of the storage capacitor, there is a known technique using a tantalum oxide (metal oxide) film having a higher dielectric constant as a capacitor insulation film. A process for forming such a capacitor insulation film includes the steps of depositing a tantalum oxide film on a polysilicon layer configuring the bottom electrode of the capacitor by using a CVD (chemical vapor deposition) technique, and crystallizing the thus deposited tantalum oxide film by using a heat treatment in an oxidizing ambient.

It is note here that the crystallized tantalum oxide film scarcely has the function of suppressing the leakage current penetrating therethrough. Therefore, it is essential to provide another insulation film having a function of suppressing the leakage current at the interface between the tantalum oxide film and the bottom electrode or top electrode of the capacitor, if the tantalum oxide film is used as the capacitor insulation film, in order for maintaining the charge retention capability of the capacitor. Thus, a silicon oxide film is formed between the tantalum oxide film and the top or bottom electrode including polysilicon by using oxidation of the polysilicon. The silicon oxide film is formed between the tantalum oxide film and the bottom electrode, for example, by using the heat treatment for crystallization of the tantalum oxide film at a temperature of 750 degrees C. or above to cause oxidation of silicon in a solid phase on the surface of the bottom electrode. This oxidation is caused by diffusion of oxygen existing in the atmosphere or tantalum oxide film toward the bottom electrode through the interface between the bottom electrode and the tantalum oxide film.

Since the silicon oxide film has a lower dielectric constant, it is not desirable to provide a silicon oxide film having a thickness larger than a specific thickness which is sufficient to prevent the leakage current, in the view point of achieving a larger capacitance for the capacitor. Thus, in order for preventing an excessive amount of oxidation in the bottom electrode, a thin silicon nitride film is formed on the bottom electrode, prior to forming the tantalum oxide film. It is to be noted however that the thin silicon nitride film may be oxidized to form a silicon oxynitride film during the heat treatment of the tantalum oxide film. If the oxygen content is larger in the resultant oxynitride film, the oxynitride film prevents improvement of the capacitor insulation film for achieving the higher capacitance. The technique using the tantalum oxide film as the capacitor insulation film is described in Patent Publications JP-1995-169917 and -1986-36963A, for example.

In the technique as described above, since the oxidation of silicon is performed by the oxygen diffused through or from the tantalum oxide film, i.e., metal oxide film, toward the bottom electrode, the thickness of the resultant oxynitride film has a significant range of variation due to a lower controllability of oxidation. A larger range of variation in the thickness of the oxynitride film causes a larger range of variation of the leakage current. Accordingly, in order for achieving a capacitor having a larger capacitance per unit area and yet a lower leakage current, it is generally necessary to provide a silicon oxynitride film having a minimum thickness between the metal oxide film and the bottom electrode, the minimum thickness achieving an effective suppression of the leakage current.

### SUMMARY OF THE INVENTION

In view of the above, it is an object of the present invention to provide a method for manufacturing a semiconductor device including a capacitor, which is capable of improving the controllability of the thickness of the silicon oxynitride film interposed between a metal oxide film and the bottom electrode, to achieve a capacitor having a larger capacitance per unit area and a smaller leakage current.

The present invention provides a method for manufacturing a semiconductor device comprising: forming a silicon film overlying a semiconductor substrate at a first substrate temperature; forming a first capacitor insulation film including silicon oxide or silicon oxynitride on the silicon film; forming a second capacitor insulation including a metal oxide on the first capacitor insulation film; thermally treating at least the second capacitor insulation at a second substrate temperature; forming a metallic film on the second capacitor insulation film; and configuring a capacitor including the silicon film, the first and second capacitor insulation films and the metallic film, wherein the second substrate temperature is lower than a maximum of the first substrate temperature.

The above and other objects, features and advantages of the present invention will be more apparent from the following description, referring to the accompanying drawings.

### BRIEF DESCRIPTION OF THE DRAWINGS

FIG. 1 is a schematic sectional view of a semiconductor device including a capacitor manufactured by a method according to an embodiment of the present invention.

FIG. 2 is a flowchart showing the procedure for manufacturing the semiconductor device according to the embodiment.

FIG. 3 is a graph showing the relationship between the capacitance and the leakage current in capacitors of samples of the embodiment and comparative examples.

FIG. 4 is a graph showing the relationship between the capacitance and the product yield of the semiconductor devices of the samples of the embodiment and comparative examples.

### PREFERRED EMBODIMENT OF THE INVENTION

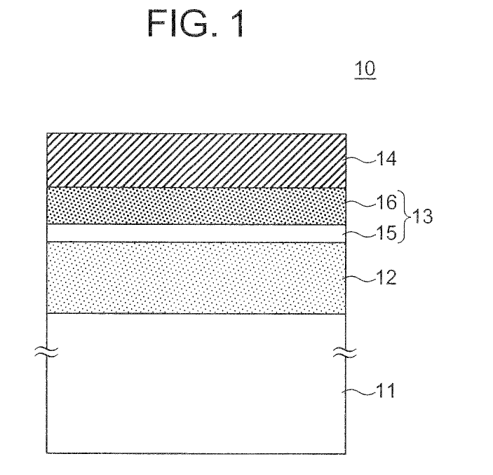

Now, an exemplary embodiment of the present invention will be described with reference to accompanying drawings. FIG. 1 schematically shows the structure of a capacitor in a semiconductor device manufactured by a method according to an embodiment of the present invention. The semiconductor device 10 is a configured as a DRAM device, for example, and includes an array of memory cells each including a MOSFET (not shown) formed in an underlying structure 11 and a capacitor depicted in the figure.

The capacitor includes a bottom electrode 12, a capacitor insulation film 13, and a top electrode 14. The bottom electrode 12 is configured by a polysilicon film heavily-doped with phosphor. The capacitor insulation film 13 has a two-layer structure including a 2-nm-thick silicon oxynitride (SiON) film 15 and an overlying 9-n-thick tantalum oxide (Ta₂O₅) film 16. Although not illustrated, the bottom electrode 12 has a hemispherical grained structure including a plurality of hemispherical grains on the surface. The top electrode 14 is configured by a titanium nitride (TiN) film. The underlying structure 11 includes contact plugs (not shown) each for connecting the MOSFET and the bottom electrode 12.

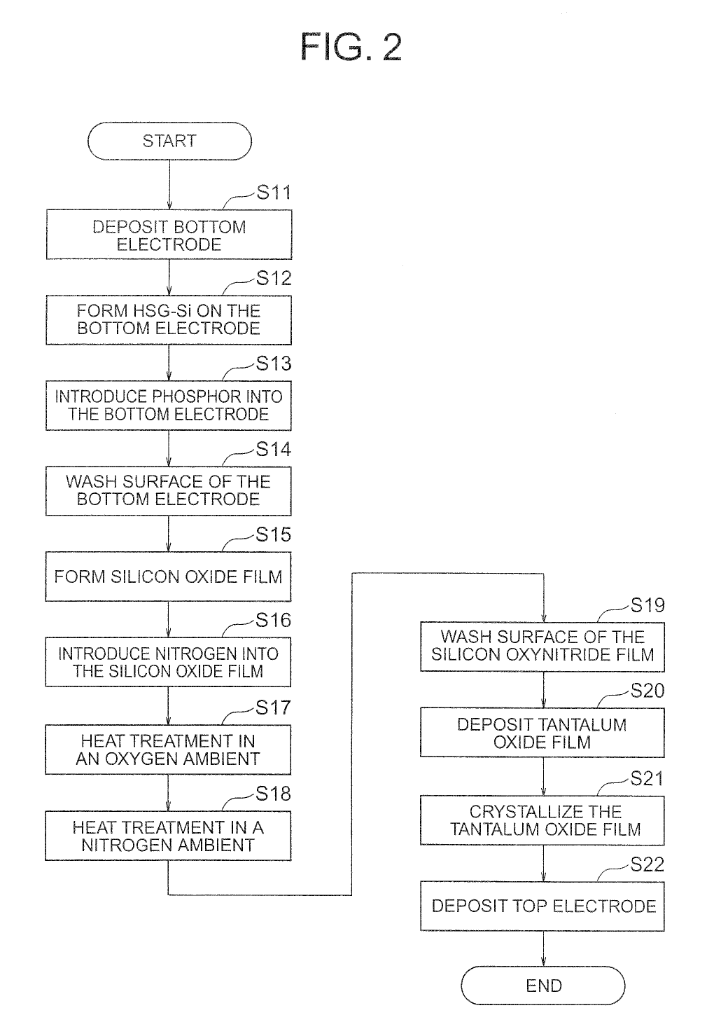

FIG. 2 shows the procedure for forming the capacitor shown in FIG. 1. First, a low-pressure CVD process using monosilane (SiH₄) and phosphine (PH₃) as a source gas is performed to deposit an amorphous silicon film on the underlying structure 11, the amorphous silicon film being heavily-doped with phosphor (Step S11). Subsequently, using a known technique, a HSG (hemi-spherical-grained) structure is formed on the surface of the deposited amorphous silicon film, which is modified in the property at the same time into a polysilicon film configuring the bottom electrode 12 (Step S12).

Subsequently, using a low-pressure CVD chamber, the bottom electrode 12 is further doped through the surface of the polysilicon film with phosphor for the purpose of suppression of depletion during operation thereof, by using PH₃ gas and a substrate temperature of 750 degrees C. (Step S13). The surface of the bottom electrode 12 is then washed using a mixture of ammonia solution and hydrogen peroxide solution (Step S14).

Subsequently, a 2-nm-thick silicon oxide film is formed on the surface of the polysilicon bottom electrode 12 by using a thermal oxidation technique (Step S15). In this thermal oxidation treatment, the substrate is heated up to a substrate temperature of 800 degrees C. by using a lamp anneal system, for example, in an oxygen ambient. Thereafter, a heat treatment is performed in an ammonia (NH₃) ambient for 2 minutes for the purpose of improvement in the relative pemittivity of the silicon oxide film, thereby introducing nitrogen into the silicon oxide film through the surface thereof to form the silicon oxynitride film 15 shown in FIG. 1 (Step S16). The nitrogen introduced into the silicon oxynitride film 15 stays near the interface between the silicon oxynitride film 15 and the bottom electrode 12, or near the top surface of the silicon oxynitride film 15.

Subsequently, another heat treatment is performed in an oxygen ambient for he purpose of reduction in the energy level of the interface between the polysilicon film configuring the bottom electrode 12 and the silicon oxynitride film 15 (Step S17). In this heat treatment, using a lamp anneal system, the substrate is heated up to a substrate temperature of 800 degrees C., which is held for 60 seconds. Oxygen diffuses into the silicon oxynitride film 15, moderately oxidizing the surface of the polysilicon film configuring the bottom electrode 12 to thereby reduce the energy level of the interface.

Thereafter, another heat treatment is performed in a nitrogen ambient, for the purpose of reduction of the fixed electric charge in the silicon oxynitride film 15 (Step S18). In this heat treatment, using a lamp anneal system, the substrate is heated up to a substrate temperature of 800 degrees C., which is maintained for 60 seconds. The nitrogen ambient may be replaced by another non-oxidizing ambient such as including argon and helium.

It is generally considered that a higher substrate temperature in the heat treatment for modification of the silicon oxynitride film 15, reduction in the energy level in the interface and reduction in the fixed charge in the silicon oxynitride film 15 may provide a superior result in the oxygen ambient and nitrogen ambient. However, an excessively higher temperature may have an adverse affect on the characteristics of MOSFETs formed prior to the heat treatment. Thus, the substrate temperature is set at 800 degrees C. in the present embodiment. The order of the heat treatments in the oxygen (oxidizing) ambient and the nitrogen (non-oxidizing) ambient may be reversed.

The surface of silicon oxynitride film 15 is then washed using a mixture of sulfuric acid and hydrogen peroxide solution (Step S19), followed by a low-pressure CVD process at a substrate temperature of 430 degrees C. and a chamber pressure of 0.5 Torr to deposit a 9-nm-thick tantalum oxide film 16 on the silicon oxynitride film 15, by using pentaethoxy tantalum (Ta(OC₂H₅)₅) and oxygen (O₂) as a source gas (Step S20). Thereafter, another heat treatment is performed in an oxidizing ambient to crystallize the tantalum oxide film 16 (Step S21).

The above heat treatment of step S21 in the oxidizing ambient is performed to suppress an oxidation reaction on the surface of the polysilicon layer configuring the bottom electrode 12, and performed at a substrate temperature of 700 degrees C., for example, which is lower than the substrate temperature in the heat treatment for forming the silicon oxynitride film 15, heat treatment in the oxygen ambient, and heat treatment in the nitrogen ambient. The heat treatment of step S21 is performed within a chamber for 10 minutes. Thus, the capacitor insulation film 13 including the silicon oxynitride film 15 and crystallized tantalum oxide film 16 is obtained.

Thereafter, the top electrode 14 is formed by depositing titanium nitride on the capacitor insulation film 13 by using TiCl₄ and NH₃ as a source gas (Step S22). Thus, the capacitor including the bottom electrode 12, capacitor insulation film 13 and top electrode 14 is formed, as shown in FIG. 1.

In the present embodiment, the substrate temperature in the heat treatment for crystallizing the tantalum oxide film 16 is lower than the substrate temperature used in the heat treatment for forming the silicon oxynitride film 15, heat treatment in the oxygen ambient and heat treatment in the nitrogen ambient. This suppresses oxidation of the surface of the polysilicon film configuring the bottom electrode 12 in a solid phase. The oxygen ambient in the embodiment may be replaced by another oxidizing ambient using a suitable oxidizing gas.

Since the oxidation reaction is suppressed during the heat treatment for crystallizing the tantalum oxide film 16, controllability of the thickness of the silicon oxynitride film 15 is improved. Thus, the silicon oxynitride film 15 has a superior uniformity in the thickness thereof, which suppresses occurring of a weak spot whereat the thickness is smaller. Suppression of the range of variation in the thickness of the silicon oxynitride film 15 reduces the leakage current and reduces the average thickness thereof. Thus, the resultant capacitor has a larger capacitance per unit area while suppressing reduction in the product yield of the semiconductor device.

Suppression of the oxidation reaction on the polysilicon film reduces the interface level or energy level at the interface between the bottom electrode 12 and the silicon oxynitride film 15, and reduces the fixed electric charge within the silicon oxynitride film 15. In addition, the heat treatment in the oxygen ambient and heat treatment in the nitrogen ambient performed prior to formation of the tantalum oxide film 16 further reduces the energy level at the interface between the bottom electrode 12 and the silicon oxynitride film 15, and reduces the fixed electric charge within the silicon oxynitride film 15. Thus, change of the flat-band voltage during applying a voltage across the capacitor insulation film is effectively reduced, to thereby provide a stabilized performance for the capacitor.

In the above embodiment, the thermal oxidation for forming the silicon oxynitride film 15, heat treatment in the oxygen ambient, and heat treatment in the nitrogen ambient use a substrate temperature of 800 degrees C. In general, a higher temperature in the thermal oxidation for forming the silicon oxynitride film provides a higher degree of density for the resultant silicon oxynitride film. The film density of the silicon oxynitride film 15 is maintained at the density obtained at he maximum temperature experienced by the silicon oxynitride film.

Therefore, if the last thermal process among the three heat treatments including the thermal oxidation is performed at a temperature higher than the temperature of the crystallizing treatment of the tantalum oxide film, the film quality of the silicon oxynitride film 15 is scarcely changed during crystallizing the tantalum oxide film. In addition, the oxidation reaction of the surface of the polysilicon film in the solid phase is also suppressed. The temperature dependency of the impurity distribution of the film is also considered similar to that of the film density so that a higher substrate temperature provides a higher stability in the impurity distribution. Thus, the crystallization temperature of the tantalum oxide film lower than the temperature in the heat treatments is unlikely to affect the impurity distribution achieved by a higher temperature.

Samples of the semiconductor device were manufactured using a process of the above embodiment. Other semiconductor devices were also manufactured as comparative examples by using a conventional technique. The comparative examples were such that the silicon oxynitride film was directly formed on the polysilicon film by using a thermal nitriding process, wherein the polysilicon film is maintained in an ammonia ambient at a substrate temperature of 750 degrees C. for a minute, to form a 1.5-nm-thick silicon oxynitride film thereon.

During manufacturing the comparative examples, the heat treatment for crystallizing the tantalum oxide film 16 was performed in a dinitrogen monoxide (N₂O) ambient at a substrate temperature of 750 degrees C., which is similar to the substrate temperature at which the silicon oxynitride film was formed. This heat treatment causes an oxidation reaction on the surface of the polysilicon film 15 configuring the bottom electrode 12, to thereby form a 3.5- to 4.0-nm-thick silicon oxynitride film 15 having a higher oxygen content.

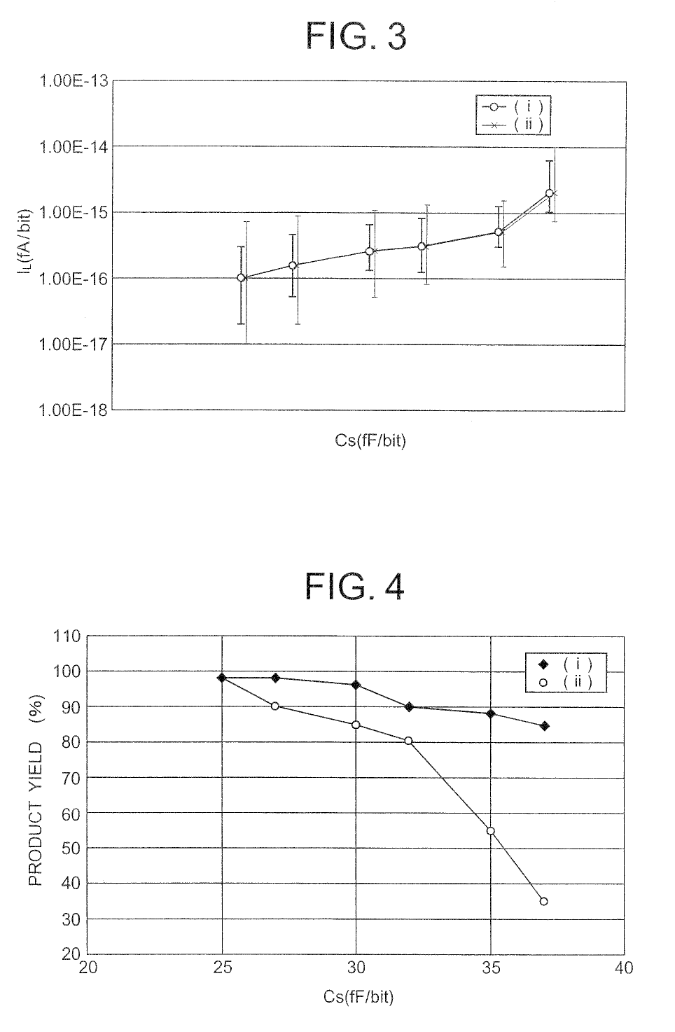

FIG. 3 shows the relationship between the capacitance (Cs) and the leakage current (I_{L}) for the test element group (TEG), i.e., samples and comparative examples. The relationship is obtained by varying the thickness of the tantalum oxide film 16 among the samples and comparative examples to intentionally change the capacitance Cs. In FIG. 3, graph (i) represents the results of samples, whereas graph (ii) represents the results of comparative examples. In these graphs, each capacitance Cs corresponds to a specific thickness of the tantalum oxide film in the samples and comparative examples. The capacitance Cs reduces along with reduction in the thickness of the capacitor insulation film 13. On the other hand, the leakage current I_{L} has a tendency of increasing together with reduction in the thickness of the capacitor insulation film 13. Thus, the leakage current I_{L} and the capacitance Cs have the relationship of a tradeoff therebetween.

In the graphs of the FIG. 3, the average of the leakage current is comparable between the samples and the comparative examples at each capacitance. However, the range of variation at each capacitance Cs is smaller in the samples than in the comparative examples. This is considered to result from the fact that the improved controllability of the thickness of the tantalum oxide film in the present embodiment effectively suppresses the range of variation in the thickness of the tantalum oxide film 15.

FIG. 4 shows the relationship between the capacitance Cs and the product yield for the above samples and comparative examples. The term “product yield” as used herein means the ratio of the number of non-effective products to the number of the total products. The non-effective products in this example were such that the charge retention rate of the capacitor is 128 milliseconds or above at the state of holding data “0”. Similarly to FIG. 3, graph (i) represents results of samples, whereas graph (ii) represents the results of comparative examples.

It is understood from FIG. 4 that number of comparative examples having a data retention rate smaller than the allowable level abruptly increases with an increase of the capacitance Cs to thereby reduce the product yield. On the other hand, in the samples, the reduction in the product yield with an increase of the capacitance Cs is significantly suppressed. Thus, it is concluded that the method of the above embodiment alleviates the tradeoff between the leakage current and the capacitance to provide a higher product yield as well as a higher capacitance per unit area.

As described heretofore, in accordance with the method of the above embodiment, the substrate temperature at which the tantalum oxide film is thermally crystallized is lower than the substrate temperature at which the silicon oxynitride film is formed. This suppresses oxidation of the polysilicon layer configuring the bottom electrode in a solid phase, thereby improving the controllability of the thickness of the silicon oxynitride layer. Thus, the capacitor insulation film formed by the method has a thickness sufficient for suppressing the leakage current while maintaining a desired capacitance per unit area.

The present invention may have the following embodiments.

The step of forming the first capacitor insulation film may include depositing a silicon oxide film or silicon oxynitride film, and thermally treating the silicon oxide film or silicon oxynitride film in an oxidizing ambient.

The step of forming the first capacitor insulation film may further include, prior to or subsequent to the thermally treating in the oxygen ambient or oxidizing ambient, thermally treating the silicon oxide film or silicon oxynitride film in a non-oxidizing ambient.

The step of forming the first capacitor insulation film may include thermally oxidizing a surface region of the silicon film to form a silicon oxide film, and introducing nitrogen into the silicon oxide film.

The metal oxide configuring the second capacitor insulation film may be selected from the group consisting of tantalum oxide, zirconium oxide and hafnium oxide.

The nonoxidizing ambient may include at least one of nitrogen, argon and helium.

The method of the present invention is suitably applied to manufacture of a semiconductor device such as used in a portable electronic device which particularly requires a lower power dissipation.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A method for manufacturing a semiconductor device comprising:
forming a silicon film overlying a semiconductor substrate at a first substrate temperature;
forming a first capacitor insulation film including silicon oxide or silicon oxynitride on said silicon film;
forming a second capacitor insulation including a metal oxide on said first capacitor insulation film;
thermally treating at least said second capacitor insulation at a second substrate temperature;
forming a metallic film on said second capacitor insulation film; and
configuring a capacitor including said silicon film, said first and second capacitor insulation films and said metallic film,
wherein said second substrate temperature is lower than a maximum of said first substrate temperature.

2. The method according to claim 1, wherein said thermally treating crystallizes said metal oxide in said second capacitor insulation film.

3. The method according to claim 1, wherein said second substrate temperature is below 750 degrees C.

4. The method according to claim 1, wherein said first capacitor insulation film forming comprises depositing a silicon oxide film or silicon oxynitride film, and thermally treating said silicon oxide film or silicon oxynitride film in an oxidizing ambient.

5. The method according to claim 4, wherein said first capacitor insulation film forming further comprises, prior to or subsequent to said thermally treating in said oxidizing ambient, thermally treating said silicon oxide film or silicon oxynitride film in a non-oxidizing ambient.

6. The method according to claim 1, wherein said first capacitor insulation film forming comprises thermally oxidizing a surface region of said silicon film to form a silicon oxide film, and introducing nitrogen into said silicon oxide film.

7. The method according to claim 1, wherein said metal oxide is selected from the group consisting of tantalum oxide, zirconium oxide and hafnium oxide.
